(19) United States
(12) Patent Application Publication
(10) Pub. No.: US 2009/0115413 A1
(43) Pub. Date: May 7, 2009

(54) DEVICE AND METHOD FOR PARALLEL MAGNETIC RESONANCE IMAGING

(75) Inventors: Julien Senegas, Hamburg (DE); Holger Eggers, Ellerhoop (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 12/064,492

(22) PCT Filed: Aug. 18, 2006
(86) PCT No.: PCT/IB2006/052862

§ 371 Date: Jul. 21, 2008

(30) Foreign Application Priority Data
Aug. 23, 2005 (EP) 05107723.8

(51) Int. Cl. G01R 33/48

(52) U.S. Cl. 324/309

(57) ABSTRACT

The invention relates to a device (1) for magnetic resonance imaging of a body (7) placed in a stationary and substantially homogeneous main magnetic field. In order to provide an MR device (1) which is able to reconstruct a final complex image of high quality, the invention proposes that the device is arranged to simultaneously acquire MR signals via the receiving antennas (10a, 10b, 10c) with subsampling of k-space, compute intermediate MR signal data at a complete set of k-space positions from the acquired MR signals, wherein the intermediate MR signal data values are calculated as linear combinations of the acquired MR signal samples using weighting factors, which weighting factors are derived from the covariances of the acquired MR signal samples, and to reconstruct an MR image from the intermediate MR signal data.

The invention relates to a device for magnetic resonance (MR) imaging of a body placed in a stationary and substantially homogeneous main magnetic field.

Furthermore, the invention relates to a method for parallel MR imaging and to a computer program for a MR imaging device.

In MR imaging, pulse sequences consisting of RF and magnetic field gradient pulses are applied to an object (a patient) to generate phase encoded MR signals, which are acquired by means of receiving antennas in order to obtain information from the object and to reconstruct images thereof. Since its initial development, the number of clinical relevant fields of application of MR imaging has grown enormously. MR imaging can be applied to almost every part of the body, and it can be used to obtain information about a number of important functions of the human body. The pulse sequence which is applied during an MR imaging scan determines completely the characteristics of the reconstructed images, such as location and orientation in the object, dimensions, resolution, signal-to-noise ratio, contrast, sensitivity for movements, etcetera. An operator of an MR device has to choose the appropriate sequence and has to adjust and optimize its parameters for the respective application.

In known parallel MR imaging techniques, multiple receiving antennas (RF coils) with different spatial sensitivity profiles are employed to reduce the scan time for a diagnostic image. This is achieved by subsampling of k-space, i.e. acquiring a smaller set of phase encoded MR signals than would actually be necessary to completely cover the predetermined field of view in accordance with Nyquist's theorem.

In the known so-called SENSE technique (see for example Pruessmann et al, MR in Medicine, volume 42, page 952, 1999), MR signals are acquired simultaneously in a subsampled fashion via multiple surface receiving coils of a MR device. The number of phase encoding steps in k-space is reduced relative to the number of phase encoding steps actually required for the complete predetermined field of view in geometrical space. This subsampling results in a reduced field of view. In conformity with the SENSE technique, images are reconstructed from the subsampled data separately for each receiving coil. Because of the subsampling, these images contain fold-over or so-called aliasing artefacts. On the basis of the known spatial sensitivity profiles of the receiving coils, the individual contributions to the folded-over image values of the reconstructed images can be decomposed (unfolded) by means of matrix computations into image values at spatial positions within the full field of view. The result is an aliasing-free image of the magnetization signal. In this way, the spatial encoding of the acquired MR signals by the spatial sensitivity profiles of the receiving coils is made use of in order to considerably accelerate the image acquisition procedure. When the known SENSE technique is employed for the computation of the final image of the complete field of view, the ratio of the dimensions of the full field of view relative to the reduced field is also referred to as reduction factor or simply as SENSE factor.

In generalized SENSE imaging strategies, the computation of the final image involves the inversion of a large, so-called encoding matrix which is determined by the spatial sensitivity profiles of the receiving antennas. Practical challenges arise in the direct inversion of this matrix. This is simply because the matrix inversion can be very memory and computation intensive, especially for non-Cartesian sampling of the MR signal data. Furthermore, at large reduction factors the encoding matrix becomes poorly conditioned, making the inversion unstable and therefore leading to undesirable noise amplification.

The aforementioned issues are addressed by the known PARS technique (Yeh et al, MR in Medicine, volume 53, page 1383, 2005). PARS stands for parallel MR imaging with adaptive radius in k-space. In accordance with the PARS technique coil signal data values are computed using acquired MR signal samples that lie within a small and adjustable radius in k-space from the sampling positions to be reconstructed. As a result of this computation, which is performed by means of a least squares fit procedure, MR signal data sets with complete sampling of k-space are obtained for each receiving antenna. Images associated with the individual receiving antennas are reconstructed from these completed signal data sets. The final MR image is obtained as sum of squares of the image values of the individual images.

It is a known problem of the PARS technique that individual coil images are first reconstructed and then combined into a magnitude image of the complete field of view. The reconstructed image does not contain phase information and has an inhomogeneous intensity due to inhomogeneous coil sensitivity profiles. Moreover, its performance in terms of SNR (signal to noise ratio) is not satisfying. This is mainly due to the sum of squares approach for generation of the final image. A further drawback of PARS is that the least squares fit procedure used for estimating the signal samples relies on the a priori knowledge of the spatial sensitivity profiles of the individual receiving antennas. Because of several matrix multiplication operations, which are involved in the PARS reconstruction procedure, the computational efficiency is suboptimal.

Therefore it is readily appreciated that there is a need for an improved technique for parallel MR imaging which enables computationally efficient and accurate image reconstruction. It is a further object of the present invention to provide an MR device for parallel imaging which is arranged to reconstruct a final image without the necessity of a priori knowledge of the spatial sensitivity profiles of the individual receiving antennas.

In accordance with the present invention, a device for MR imaging of a body placed in a stationary and substantially homogeneous main magnetic field is disclosed. The device is provided with receiving antennas which have different sensitivity profiles for receiving phase encoded MR signals from the body. The device of the invention is arranged to

simultaneously acquire MR signals via the receiving antennas,

compute intermediate MR signal data at a complete set of k-space positions from the acquired MR signals, wherein the intermediate MR signal data values are calculated as linear combinations of the acquired MR signal samples using weighting factors, which weighting factors are derived from the covariances of the acquired MR signal samples,

reconstruct an MR image from the intermediate MR signal data.

The invention advantageously enables the fast and robust generation of high quality MR images from (preferably, but not necessarily subsampled) MR signals acquired in parallel via two or more receiving antennas. In accordance with the invention the intermediate MR signal data is computed directly from the acquired MR signals. This intermediate MR signal data is a single completely sampled MR data set containing only magnetization information. It corresponds to an MR signal data set in k-space that would have been acquired with a receiving antenna having a spatially homogeneous sensitivity (e.g. a body coil). The final image is then reconstructed from the completely sampled intermediate MR signal data set. Consequently, no sum of squares computation (as required by the PARS technique) is necessary. This has a significant positive effect on image quality. The invention is further based upon the insight that linear statistical estimation can be used for reconstruction of MR signal samples instead of the least squares approach applied in accordance with the PARS technique. According to the invention the intermediate MR signal data values are calculated as linear combinations of the acquired MR signal samples using weighting factors. These weighting factors are simply derived from the covariances of the acquired MR signal samples. It is an advantage of the invention that the covariances can be computed straightforward from the acquired MR signal samples. The a priori knowledge of the spatial sensitivity profiles of the receiving antennas is not necessarily required. On the other hand, it is a further advantage of the invention that the covariances can be computed very efficiently from the sensitivity data, if available, by making use of the Fourier transform (see below).

In accordance with the present invention it is advantageous to compute each intermediate MR signal data value at a given k-space position as a linear combination of only a limited number of MR signal samples acquired at neighbouring k-space positions. In this way the k-space locality in the MR data encoding by the respective spatial sensitivity profiles is exploited. The computation of the weighting factors from the covariances may involve solving a system of linear equations. In accordance with the invention only MR signal samples within a local neighbourhood in k-space from each sampling position to be reconstructed may be considered. This determines the size of the system of linear equations to be solved, respectively. The size and shape of the neighbourhood has thus to be selected such that an optimum tradeoff between image quality and computation speed is achieved. It lies within the scope of the invention to select an arbitrary subset from the acquired MR signal data in order to reconstruct the intermediate MR signals therefrom.

As stated above, the MR device of the invention may be arranged to derive the covariances directly from the acquired MR signals without including separate data (such as previously acquired calibration data) relating to the spatial sensitivity profiles of the receiving antennas in the computation. But it is also possible to derive the covariances from the spatial sensitivity profiles if they are known a priori. As mentioned before, the computation of the covariances can be performed very efficiently in this case by using known Fourier transformation algorithms. An advantage of the invention is that it offers different opportunities to calculate the weighting factors for reconstruction depending on whether the sensitivity data of the receiving antennas is available or not.

A major advantage of the invention is that the MR signals may be acquired adopting a non-Cartesian sampling scheme without increasing the computational complexity of the method. For example a radial or a spiral acquisition can be employed. The k-space positions covered by the intermediate MR signal data set can be selected arbitrarily, irrespective of the sampling scheme of the MR signal acquisition. It is for example possible to compute the intermediate MR signal data by using a Cartesian sampling pattern while the MR signals are acquired radially. This allows for the direct reconstruction of the final MR image by means of a Fourier transform of the intermediate data without any additional regridding steps. One alternate choice for the k-space pattern of the intermediate data may be to use the same pattern as in the acquisition but without subsampling. This presents advantages for defining the shape of the local neighbourhoods.

A further aspect is that the invention is very well suited for dynamic MR imaging (e.g. CINE acquisitions). Since the spatial sensitivity profiles of the receiving antennas do not change during the acquisition of a plurality of consecutive images, the weighting factors and covariances have to be computed only once and can then be used repeatedly for the reconstruction of each image. Thus the computational complexity for image reconstruction in dynamic parallel imaging is significantly reduced as compared to prior art approaches.

The invention is not limited to sub-sampling strategies in k-space, but can also be applied to reconstruct series of images acquired with a sub-sampling strategies in a multi-dimensional space (e.g. kt-space, which is the space spanning both k-space and the time dimension). In that case, an arbitrary position in this multi-dimensional space can be reconstructed from data acquired at neighbouring positions, wherein neighbouring data in all dimensions of the multi-dimensional space can be considered.

The invention not only relates to a device but also to a method for MR imaging of at least a portion of a body placed in a stationary and substantially homogeneous main magnetic field, the method comprising the following steps:

simultaneously acquiring MR signals (with or without subsampling of k-space) via two or more receiving antennas having different sensitivity profiles,

computing intermediate MR signal data at a complete set of k-space positions from the acquired MR signals, wherein the intermediate MR signal data values are calculated as linear combinations of the acquired MR signal samples using weighting factors, which weighting factors are derived from the covariances of the acquired MR signal samples,

reconstructing an MR image from the intermediate MR signal data.

A computer program adapted for carrying out the imaging procedure of the invention can advantageously be implemented on any common computer hardware, which is presently in clinical use for the control of MR scanners. The computer program can be provided on suitable data carriers, such as CD-ROM or diskette. Alternatively, it can also be downloaded by a user from an Internet server.

The following drawings disclose preferred embodiments of the present invention. It should be understood, however, that the drawings are designed for the purpose of illustration only and not as a definition of the limits of the invention. In the drawings

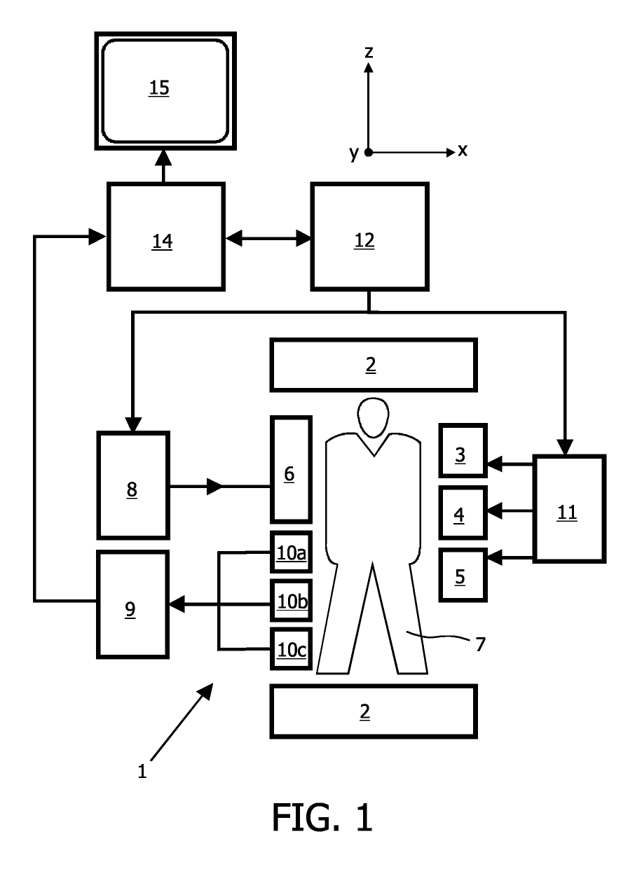

FIG. 1 shows an embodiment of a magnetic resonance scanner according to the invention,

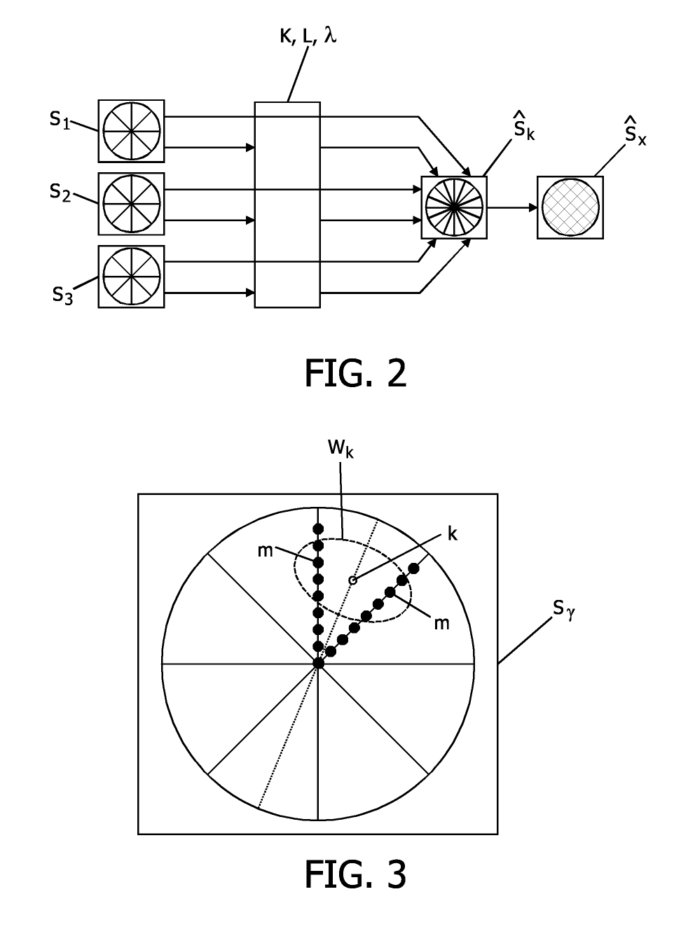

FIG. 2 illustrates the method of the invention as a block diagram,

FIG. 3 shows a diagramatic representation of the selection of the k-space positions during computation of the intermediate MR signal data in accordance with the invention.

In FIG. 1 a MR imaging device 1 in accordance with the present invention is shown as a block diagram. The apparatus 1 comprises a set of main magnetic coils 2 for generating a stationary and homogeneous main magnetic field and three sets of gradient coils 3, 4 and 5 for superimposing additional magnetic fields with controllable strength and having a gradient in a selected direction. Conventionally, the direction of the main magnetic field is labelled the z-direction, the two directions perpendicular thereto the x- and y-directions. The gradient coils are energized via a power supply 11. The apparatus 1 further comprises a radiation emitter 6, an antenna or coil, for emitting radio frequency (RF) pulses to a body 7, the radiation emitter 6 being coupled to a modulator 8 for generating and modulating the RF pulses. Also provided are receiving antennas 10a, 10b, 10c for receiving the MR signals, the receiving antennas can for example be separate surface coils with different spatial sensitivity profiles. The received MR signals are input to a demodulator 9. The modulator 8, the emitter 6 and the power supply 11 for the gradient coils 3, 4 and 5 are controlled by a control system 12 to generate the actual imaging sequence for parallel signal acquisition. The control system is usually a microcomputer with a memory and a program control. For the practical implementation of the invention it comprises a programming with a description of an imaging procedure as described above. The demodulator 9 is coupled to a data processing unit 14, for example a computer, for transformation of the acquired MR signals into an image in accordance with the invention. This MR image can be made visible, for example, on a visual display unit 15.

FIGS. 2 and 3 illustrate the image reconstruction strategy of the invention. The method starts with the parallel (subsampled) acquisition of three (or more) MR signal data sets S_{1,m}, S_{2,m}, S_{3,m} via separate receiving antennas with different sensitivity profiles. The indices 1, 2, and 3 denote the respective receiving antenna, and the index m identifies the position in k-space. In the depicted example a radial k-space sampling scheme is employed. In accordance with the invention, an intermediate MR signal data set Ŝₖ is computed at a complete set of k-space positions k. In the depicted embodiment, the intermediate data set Ŝₖ uses the same radial sampling pattern as the acquired MR signals S_{1,m}, S_{2,m}, S_{3,m}, but without subsampling. The data values Ŝₖ are calculated as linear combinations of the acquired signal samples S_{1,m}, S_{2,m}, S_{3,m} in accordance with the following formula:

$${S}_{k} = {\sum }_{γ = 0}^{{n}_{c} - 1} {\sum }_{m ∈ {W}_{k}} {λ}_{γ , m} {S}_{γ , m} ,$$

wherein n_{c} stands for the number of antennas (e.g. three), λ_{γ,m} are weighting factors, and mεWₖ means that only signal samples S_{γ,m} within an adjustable neighbourhood (Wₖ) in k-space from sampling position k are considered. Following the theory of optimal statistical inference the weighting factors are derived from the covariances of the acquired MR signals. This yields:

Kλ=L, wherein

K_{γ}_{₁}_{,m}_{₁}_{,γ}_{₂}_{,m}_{₂}=Cov(S_{γ}_{₁}_{,m}_{₁},S_{γ}_{₂},m_{₂}) and L_{γ,m}=Cov(S_{γ,m},Sₖ).

This implies that the estimation variance Var(Sₖ−Ŝₖ) is minimized. In accordance with the invention, the computation of each intermediate data value Ŝₖ involves the collection of all k-space samples S_{γ,m} in the considered neighbourhood Wₖ of sampling position k. Then the covariances L_{γ,m} and K_{γ}_{₁}_{,m}_{₁}_{,γ}_{₂}_{,m}_{₂} with mεWₖ, m₁εWₖ, and m₂εWₖ are calculated for all γ,γ₁,γ₂=0 . . . n_{c}−1. Finally, the linear system of equations Kλ=L is solved (e.g. by means of a Cholesky decomposition) in order to obtain the weighting factors λ_{γ,m}. Then the further computation of the intermediate data values Ŝₖ is straightforward. After complete computation of Ŝₖ the final MR image values Ŝₓ (x represents a point in geometrical space) is reconstructed by means of Fourier transform techniques (including a gridding step if necessary).

So far, all acquired signals S_{γ,m} were considered to be noiseless. If statistical information about the noise present during MR signal acquisition is available, this information can easily be incorporated into the above calculation. The values of noise correlation matrix Ψ may be added to the covariance matrix K in order to obtain a regularization that takes the noise into account (L remains unchanged). This has the advantage of avoiding noise amplification in the reconstruction.

If the sensitivity profiles c_{γ,x} of the receiving antennas are known (e.g. from a calibration scan), the covariances may be computed in accordance with the following equations:

K_{γ}_{₁}_{,m}_{₁}_{,γ}_{₂}_{,m}_{₂}=κ·FT[c_{γ}_{₁}_{,x} c̅_{γ}_{₂}_{,x}](m₁−m₂) and

L_{γ,m}=κ·FT[c_{γ,x}](m−k),

wherein FT denotes the Fourier transform in terms of the geometrical coordinate x. c_{γ}_{₁}_{,x} c̅_{γ}_{₂}_{,x} means a point-by-point product of the sensitivities c_{γ}_{₁}_{,x} and c̅_{γ}_{₂}_{,x} (complex conjugate). The covariances K and L are obviously translation invariant, i.e. they depend only on the differences m₁−m₂ and m−k, respectively. K denotes the variance of the acquired MR signals S.
In order to compute the covariances in accordance with the afore-described variant of the invention, at first the sensitivities c_{γ,x} need to be estimated (e.g. by means of a reference scan). Then all cross products c_{γ}_{₁}_{,x} c̅_{γ}_{₂}_{,x} are calculated. Finally, the Fourier transforms of the cross products and the Fourier transforms of the sensitivities are evaluated at the required positions. For Cartesian acquisitions, the differences m₁−m₂ and m−k correspond to the nodes of a Cartesian grid. An FFT (Fast Fourier Transform) algorithm may then be used for evaluating the Fourier transforms. Assuming that a neighbourhood Wₖ of equal size and shape is chosen for all intermediate data values, the matrix inversion for computing the weighting factors needs to be performed only once. For non-Cartesian acquisition, the differences m₁−m₂ and m−k do not form the nodes of a Cartesian grid and a suitable gridding algorithm is required for evaluation of the Fourier transforms. In general, the inversion of the covariance matrix K has to be repeated in this case for each sampling point of the intermediate data. Interpolation strategies may be employed in order to reduce the number of matrix inversions actually performed. It is also possible to estimate the signal S at a group of different sampling positions k on the basis of the same subset of data S_{1,m}, S_{2,m}, S_{3,m} to reduce the number of matrix inversions actually performed.

As a further alternative, the covariances may be calculated directly from the sampled MR signals by means of the following equations:

$${K}_{{γ}_{1} , {m}_{1} , {γ}_{2} , {m}_{2}} = \frac{1}{\# {m}_{1}^{′} - {m}_{2}^{′} \approx {m}_{1} - {m}_{2}} {\sum }_{{m}_{1}^{′} - {m}_{2}^{′} \approx {m}_{1} - {m}_{2}} {S}_{{γ}_{1} , {m}_{1}^{′}} {S}_{{γ}_{2} , {m}_{2}^{′}} and$$

$${L}_{γ , m} = \frac{1}{\# {m}^{′} - {k}^{′} \approx m - k} {\sum }_{{m}^{′} - {k}^{′} \approx m - k} {S}_{γ , {m}^{′}} {S}_{{k}^{′}} ,$$

wherein # denotes the cardinal of the set of considered signal samples. This variant makes explicit use of the translation invariance properties of the covariances in k-space.

1. Device for magnetic resonance (MR) imaging of a body placed in a stationary and substantially homogeneous main magnetic field, the device comprising two or more receiving antennas for receiving phase encoded MR signals from the body, which receiving antennas have different sensitivity profiles, wherein the device is arranged to
simultaneously acquire MR signals via the receiving antennas,
compute intermediate MR signal data at a complete set of k-space positions from the acquired MR signals, wherein the intermediate MR signal data values are calculated as linear combinations of the acquired MR signal samples using weighting factors, which weighting factors are derived from the covariances of the acquired MR signal samples,
reconstruct an MR image from the intermediate MR signal data.

2. Device according to claim 1, wherein the device is arranged to acquire the MR signal data with subsampling of k-space.

3. Device according to claim 1, wherein the device is further arranged to compute each intermediate MR signal data value at a given k-space position as a linear combination of a limited number of MR signal samples acquired at neighbouring k-space positions.

4. Device according to claim 1, wherein the device is further arranged to derive the covariances directly from the acquired MR signals without including separate data relating to the spatial sensitivity profiles of the receiving antennas.

5. Device according to claim 1, wherein the device is further arranged to derive the covariances from the spatial sensitivity profiles of the receiving antennas.

6. Device according to claim 5, wherein the device is arranged to compute the covariances by performing a Fourier transform of the spatial sensitivity profiles.

7. Device according to claim 1, wherein the device is arranged to compute the weighting factors from the covariances by solving a system of linear equations.

8. Device according to claim 1, wherein the device is arranged to acquire the MR signals adopting a non-Cartesian sampling scheme.

9. Device according to claim 1, wherein the device is further arranged to compute the intermediate MR signal data values at a Cartesian set of k-space positions.

10. Device according to claim 1, wherein the device is arranged to store the computed weighting factors for reconstruction of a at least one further MR image from subsequently acquired MR signals.

11. Method for parallel MR imaging of at least a portion of a body placed in a stationary and substantially homogeneous main magnetic field, the method comprising the following steps:
simultaneously acquiring MR signals via two or more receiving antennas having different sensitivity profiles,
computing intermediate MR signal data at a complete set of k-space positions from the acquired MR signals, wherein the intermediate MR signal data values are calculated as linear combinations of the acquired MR signal samples using weighting factors, which weighting factors are derived from the covariances of the acquired MR signal samples,
reconstructing an MR image from the intermediate MR signal data.

12. Method according to claim 11, wherein each intermediate MR signal data value is computed at a given k-space position as a linear combination of a limited number of MR signal samples acquired at neighbouring k-space positions.

13. Computer program for a MR imaging device, with instructions for
simultaneously acquiring MR signals with subsampling of k-space via two or more receiving antennas having different sensitivity profiles,
computing intermediate MR signal data at a complete set of k-space positions from the acquired MR signals, wherein the intermediate MR signal data values are calculated as linear combinations of the acquired MR signal samples using weighting factors, which weighting factors are derived from the covariances of the acquired MR signal samples,
reconstructing an MR image from the intermediate MR signal data.
